(19) United States
(12) Patent Application Publication
(10) Pub. No.: US 2005/0012138 A1
(43) Pub. Date: Jan. 20, 2005

(54) Nonvolatile semiconductor memory device

(75) Inventors: Seiichi Endo, Hyogo (JP); Motoharu Ishii, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/757,438

(22) Filed: Jan. 15, 2004

(30) Foreign Application Priority Data
Jul. 15, 2003 (JP) 2003-274728(P)

(51) Int. Cl. H01L 29/788

(52) U.S. Cl. 257/315

(57) ABSTRACT

A nonvolatile semiconductor memory device includes: a semiconductor substrate having a main surface; a pair of p-type impurity diffused regions, formed at the main surface of the semiconductor substrate to serve as source/drain; a floating gate formed on a region of the semiconductor substrate lying between the paired p-type impurity diffused regions, with a tunnel insulating layer interposed between the floating gate and the region of the semiconductor substrate; and an impurity diffused control region formed at the main surface of the semiconductor substrate to control a potential of the floating gate. Accordingly, a nonvolatile semiconductor device can be obtained in which data can be electrically erased and written at a low voltage.

### BACKGROUND OF THE INVENTION

1. Field of the Invention

This invention relates to a nonvolatile semiconductor memory device. More particularly, this invention relates to a nonvolatile semiconductor memory device having a memory cell of a single layer gate structure.

2. Description of the Background Art

In a conventional flash memory, a memory cell has a stacked gate structure where a floating gate is formed on a channel region with a tunnel oxide layer interposed therebetween and furthermore a control gate is formed on the floating gate with an insulating film interposed therebetween. However, such a stacked gate structure has a complex configuration and thus requires a complex manufacturing process.

Thus, in order to simplify the configuration and the manufacturing process, a memory cell having a single layer gate structure is proposed where a floating gate is the only gate on a channel region.

In a memory cell having a conventional single layer gate structure, a substrate and a floating gate are coupled via capacitive coupling. Therefore, when a voltage is applied to the substrate, a potential of the floating gate automatically approaches that of the substrate. As such, it is difficult to provide a large potential difference between the substrate and the floating gate.

Accordingly, for a memory cell having the conventional single layer gate structure, data can hardly be erased electrically and can be erased only by ultraviolet irradiation. A usage of such memory cell is thus limited to such a memory as one time programmable read-only memory (OTPROM), which is hardly rewritten.

For a memory cell having a single layer gate structure, an electrically erasable configuration is disclosed for example in National Patent Publication No. 8-506693 and Japanese Patent Laying-Open No. 3-57280.

According to the configuration, an impurity diffused region which is formed at a surface of a semiconductor substrate can be arranged to face the floating gate to control the potential thereof.

However, a memory transistor disclosed in the above two references is an n-channel metal oxide semiconductor (MOS) transistor where data writing at a low voltage is difficult. The disadvantage will be described in the following.

In a write operation, when a memory transistor is an n-channel MOS transistor, a positive high voltage is applied to the drain to cause electrons drawn from the source to move at high velocity through the channel provided at a surface of the semiconductor substrate toward the drain. The electrons are then highly energized in the vicinity of the drain, which are called hot electrons. The hot electrons are then injected into the floating gate to cause a data written state.

In this case, a positive high voltage is applied to the drain. Accordingly, if a large potential difference is not provided between the semiconductor substrate and the floating gate, the hot electrons are just injected into the drain and less injected into the floating gate. Therefore, when a memory transistor is an n-channel MOS transistor, a positive high voltage should be applied in a write operation, which disadvantageously makes data writing at a low voltage difficult.

Particularly for a single layer gate structure, since a control gate does not exist on the floating gate, a potential difference caused by capacitive coupling between the floating gate and the semiconductor substrate must be exploited to inject hot electrons into the floating gate. Accordingly, a high voltage is required for data writing though it is difficult to establish a high potential in the single layer gate structure, which disadvantageously makes a data writing operation difficult.

### SUMMARY OF THE INVENTION

An object of the present invention is to provide a nonvolatile semiconductor device in which data can be electrically erased and can be easily written at a low voltage.

A nonvolatile semiconductor memory device of the present invention includes a semiconductor substrate, a pair of p-type impurity diffused regions which is to serve as the source/drain, a floating gate, and an impurity diffused control region. The semiconductor substrate has a main surface. The pair of p-type impurity diffused regions which is to serve as the source/drain is formed at the main surface of the semiconductor substrate. The floating gate is formed on a region of the semiconductor substrate lying between the paired p-type impurity diffused regions with a tunnel insulating layer interposed between the floating gate and the region of the semiconductor substrate. The impurity diffused control region is formed at the main surface of the semiconductor substrate to control a potential of the floating gate.

According to the nonvolatile semiconductor device of the present invention, since the impurity diffused control region is formed at the main surface of the semiconductor substrate to control a potential of the floating gate, a large potential difference can easily be provided between the substrate and the floating gate and thus electrons are easily drawn from the floating gate. Consequently, electrical erasure can be made.

Since the source/drain are p-type impurity diffused regions, the memory transistor is a p-channel transistor. For the p-channel transistor in a write operation, negative side voltage is applied to the drain to cause holes provided from the source to move at high velocity through the channel provided at the surface of the semiconductor substrate toward the drain. The holes then collide against atoms in the vicinity of the drain to generate electron-hole pairs, electrons of which are then injected into the floating gate to cause a data written state.

In this case, since a negative side voltage is applied to the drain, the electrons are less easily injected into the drain while they are more easily injected into the floating gate. Accordingly, without providing not so large potential difference between the semiconductor substrate, the electrons can be injected into the floating gate and thus data can be written at a low voltage.

### BRIEF DESCRIPTION OF THE DRAWINGS

FIG. 1 is a plan view schematically showing a configuration of a semiconductor memory device in a first embodiment of the present invention.

FIGS. 2A and 2B are a schematic cross section taken along a line IIA-IIA in FIG. 1 and a schematic cross section taken along a line IIB-IIB in FIG. 1 respectively.

FIG. 3 is a schematic cross section taken along a line III-III in FIG. 1.

FIG. 4 is a plan view schematically showing a configuration of a semiconductor memory device in a second embodiment of the present invention.

FIG. 5 is a schematic cross section taken along a line V-V in FIG. 4.

FIG. 6 is a plan view schematically showing a configuration of a semiconductor memory device in a third embodiment of the present invention.

FIGS. 7A and 7B are a schematic cross section taken along a line VIIA-VIIA in FIG. 6 and a schematic cross section taken along a line VIIB-VIIB in FIG. 6 respectively.

FIG. 8 is a schematic cross section taken along a line VIII-VIII in FIG. 6.

FIG. 9 is a plan view schematically showing a configuration of a semiconductor memory device in a fourth embodiment of the present invention.

FIGS. 10A and 10B are a schematic cross section taken along a line XA-XA in FIG. 9 and a schematic cross section taken along a line XB-XB in FIG. 9 respectively.

FIG. 11 is a schematic cross section taken along a line XI-XI in FIG. 9.

FIG. 12 is a plan view schematically showing a configuration of a semiconductor memory device in a fifth embodiment of the present invention.

FIG. 13 is a schematic cross section taken along a line XIII-XIII in FIG. 12.

FIG. 14 is a plan view schematically showing a configuration of a semiconductor memory device in a sixth embodiment of the present invention.

FIGS. 15A and 15B are a schematic cross section taken along a line XVA-XVA in FIG. 14 and a schematic cross section taken along a line XVB-XVB in FIG. 14 respectively.

FIG. 16 is a plan view schematically showing a configuration of a semiconductor memory device in a seventh embodiment of the present invention.

FIG. 17 is a schematic cross section taken along a line XVII-XVII in FIG. 16.

FIG. 18 is a plan view schematically showing a configuration of a semiconductor memory device in an eighth embodiment of the present invention.

FIGS. 19A and 19B are a schematic cross section taken along a line XIXA-XIXA in FIG. 18 and a schematic cross section taken along a line XXB-XIXB in FIG. 18 respectively.

FIG. 20 is a schematic cross section taken along a line XX-XX in FIG. 18.

FIG. 21 is a plan view schematically showing a configuration of a semiconductor memory device in a ninth embodiment of the present invention.

FIGS. 22A and 22B are a schematic cross section taken along a line XXIA-XXIIA in FIG. 21 and a schematic cross section taken along a line XXIIB-XXIIB in FIG. 21 respectively.

FIG. 23 is a schematic cross section taken along a line XXIII-XXIII in FIG. 21.

FIG. 24 is a plan view schematically showing a configuration of a semiconductor memory device in a tenth embodiment of the present invention.

FIG. 25 is a schematic cross section taken along a line XXV-XXV in FIG. 24.

### DESCRIPTION OF THE PREFERRED EMBODIMENTS

Embodiments of the present invention will now be described in connection with the drawings.

First Embodiment

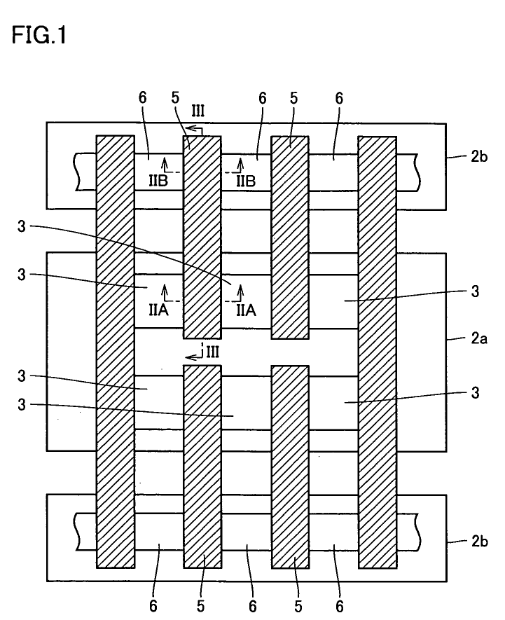

A selection transistor is not shown except for FIG. 1 and will not be described though it is typically provided for every bit in a memory cell. The reason is that the selection transistor is not related to an operating principle in the embodiment of the present invention. The selection transistor is also treated as such in other embodiments of the present invention.

Referring to FIGS. 1 to 3, a memory cell of the embodiment mainly includes a floating gate transistor 10 and a portion to control a floating gate 5.

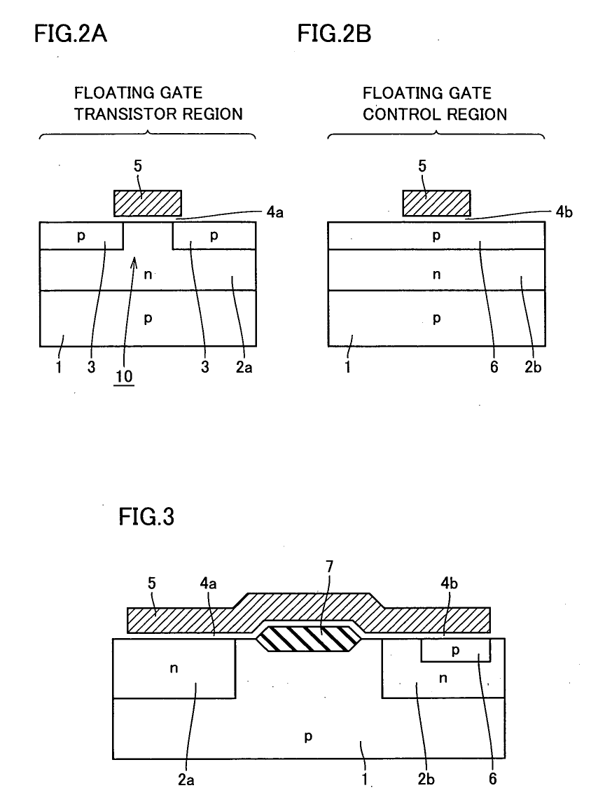

Referring to FIG. 2A, in a region where the floating gate transistor is formed, an n-type well region 2a is formed at a main surface of a p-type semiconductor substrate 1. In n-type well region 2a is formed floating gate transistor 10 which is a p-channel MOS transistor. Floating gate transistor 10 includes a pair of p-type impurity diffused regions 3, 3 which is to serve as the source/drain, a tunnel insulating layer 4a, and floating gate 5. The pair of p-type impurity diffused regions 3, 3 which is to serve as the source/drain is formed at the main surface of semiconductor substrate 1 in n-type well region 2a. Floating gate 5 is formed on a region of semiconductor substrate 1 lying between paired p-type impurity diffused regions 3, 3 with tunnel insulating layer 4a interposed between the floating gate and the region of semiconductor substrate 1.

Referring to FIG. 2B, floating gate 5 extends from the region where the floating gate transistor is formed to the floating gate control region. In the floating gate control region, an impurity diffused control region 6 is formed to control a potential of floating gate 5. Impurity diffused control region 6 is configured of a p-type impurity diffused region formed at the main surface of semiconductor substrate 1 and faces floating gate 5 with an insulating layer 4b interposed therebetween. Impurity diffused control region 6 is formed in an n-type well region 2b formed at the main surface of semiconductor substrate 1.

Referring to FIG. 3, a field insulating layer 7 is formed at the main surface of semiconductor substrate 1 between the region where the floating gate transistor is formed and the floating gate control region. A p-type region of semiconductor substrate 1 is positioned just below field insulating layer 7.

Write and erase operations of a memory cell in the embodiment will now be described. It should be noted that, in the embodiment, a “written state” of a memory cell refers to the state where electrons are accumulated at floating gate 5 while an “erased” state thereof refers to the state where electrons are drawn from floating gate 5.

Referring to FIGS. 2A and 2B, a memory cell is written by injecting into floating gate 5 hot carriers resulting from impact ionization at floating gate transistor 10. The hot carriers are generated by applying to every region a voltage shown in table 1.

TABLE 1

| REGION WHERE | |
|---|---|
| VOLTAGE IS TO BE | |
| APPLIED | VOLTAGE |
| ONE P-TYPE IMPURITY | 0 V |
| DIFFUSED REGION 3 | |
| THE OTHER P-TYPE | ˜8 V |
| IMPURITY DIFFUSED | |
| REGION 3 | |
| IMPURITY DIFFUSED | ˜10 V |
| CONTROL REGION 6 | |
| N-TYPE WELL REGION 2a | ˜8 V |
| N-TYPE WELL REGION 2b | ˜10 V |
| P-TYPE SEMICONDUCOR | 0 V |
| SUBSTRATE 1 | |

*Same voltage is applied to the other p-type impurity diffused region 3 and n-type well region 2a.
*Same voltage is applied to impurity diffused control region 6 and n-type well region 2b.

In this case, impurity diffused control region 6 serves to control a potential of floating gate 5. More particularly, a maximum amount of hot carriers is generated when the floating gate 5 potential is approximately −1V (with reference to one p-type impurity diffused region 3). Accordingly, a voltage which can cause such potential is applied to impurity diffused control region 6 to control the floating gate 5 potential.

A memory cell is erased by providing a high potential to each of one p-type impurity diffused region 3, the other p-type impurity diffused region 3, and n-type well region 2 to cause Fowler-Nordheim (FN) tunneling, by which electrons accumulated at floating gate 5 are drawn. In order to cause FN tunneling, a positive potential as shown in table 2 is provided to each of one p-type impurity diffused region 3, the other p-type impurity diffused region 3, and n-type well region 2a.

TABLE 2

| REGION WHERE | |
|---|---|
| VOLTAGE IS TO BE | |
| APPLIED | VOLTAGE |
| ONE P-TYPE IMPURITY | ˜15 V |
| DIFFUSED REGION 3 | |
| THE OTHER P-TYPE | ˜15 V |
| IMPURITY DIFFUSED | |
| REGION 3 | |
| IMPURITY DIFFUSED | ˜−15 V |
| CONTROL REGION 6 | |
| N-TYPE WELL REGION 2a | ˜15 V |
| N-TYPE WELL REGION 2b | 0 V |
| P-TYPE | 0 V |
| SEMICONDUCTOR | |
| SUBSTRATE 1 | |

*Same voltage is applied to one p-type impurity diffused region 3, the other p-type impurity diffused region 3, and n-type well region 2a.

In this case, a negative voltage as shown in table 2 is also applied to impurity diffused control region 6 to lower the floating gate 5 potential (with reference to one p-type impurity diffused region 3). To perform an efficient erase operation, junction capacitance ratios of floating gate 5 to one p-type impurity diffused region 3, the other p-type impurity diffused region 3, and n-type well region 2a respectively are preferably minimized to obtain a maximum potential difference.

According to the embodiment, since impurity diffused control region 6 can control the floating gate 5 potential, a large potential difference can be provided between semiconductor substrate 1 and floating gate 5. Consequently, electrons in floating gate 5 can be drawn by exploiting the FN tunneling, which allows data to be electrically erased.

Additionally, floating gate transistor 10 is a p-channel MOS transistor. Therefore, in a write operation, a negative voltage is applied to the drain to cause holes provided from the source to move at high velocity through the channel provided at the surface of semiconductor substrate 1 toward the drain. The holes then collide against atoms in the vicinity of the drain to generate electron-hole pairs, electrons of which are then injected into floating gate 5 to cause a data written state.

In this case, since a negative side voltage is applied to the drain, the electrons are less easily injected into the drain while they are easily injected into floating gate 5. Accordingly, without providing not so large potential difference between semiconductor substrate 1 and floating gate 5, electrons can be injected into floating gate 5 and thus data can be written at a low voltage.

Second Embodiment

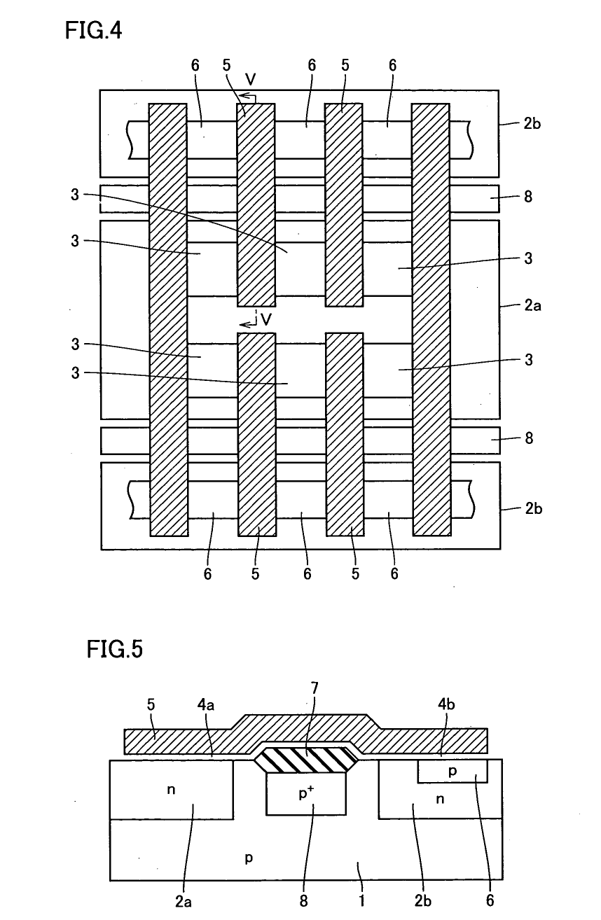

Referring to FIGS. 4 and 5, a configuration of a memory cell of the embodiment differs from that of the first embodiment in that it has a p-type impurity diffused region 8 for device isolation.

P-type impurity diffused region 8 for device isolation is formed at semiconductor substrate 1 just below field insulating layer 7 which is formed at the main surface of semiconductor substrate 1 between the floating gate transistor region and the floating gate control region. P-type impurity diffused region 8 for device isolation has higher carrier concentration than semiconductor substrate 1.

Since a configuration except for the aforementioned is almost similar to that of the first embodiment, similar reference characters are given to similar components and description thereof will not be repeated.

According to the embodiment, the following effect can be obtained.

In write and erase operations, when a voltage as shown in tables 1 and 2 is applied to n-type well regions 2a, 2b, a depletion layer is formed at pn junctions between p-type semiconductor substrate 1 and n-type well regions 2a, 2b respectively. As the depletion layer extends further, leakage current associated with the punch-through increases.

According to the embodiment, since p-type impurity diffused region 8 for device isolation has higher carrier concentration than semiconductor substrate 1, further extension of the depletion layer can be suppressed. Consequently, the distance between n-type well region 2a and n-type well region 2b can be reduced to provide a smaller-sized memory cell than the first embodiment.

Third Embodiment

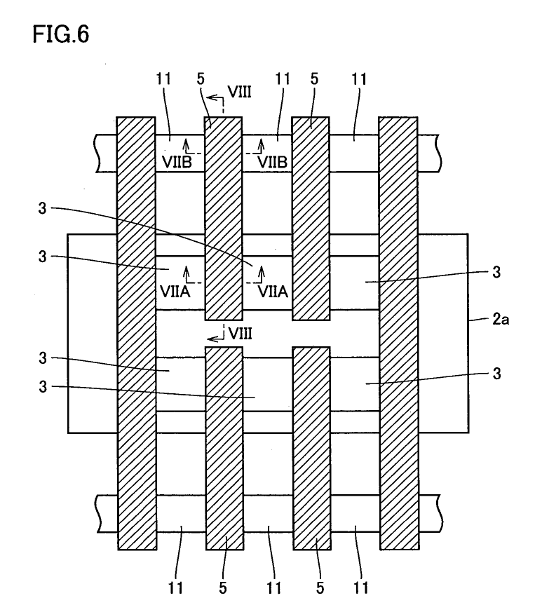

Referring to FIGS. 6 to 8, a configuration of a memory cell of the embodiment differs from that of the first embodiment in its configuration of an impurity diffused control region in the floating gate control region.

The impurity diffused control region of the embodiment is configured of a pair of n-type source/drain impurity diffused regions 11, 11. The pair of source/drain impurity diffused regions 11, 11 is formed at the main surface of p-type semiconductor substrate 1 such that a region of semiconductor substrate 1 positioned below floating gate 5 is interposed between the paired source/drain regions. The pair of source/drain impurity diffused regions 11, 11, an insulating layer 4b, and floating gate 5 configure a control transistor 20 which is an n-channel MOS transistor.

Since a configuration except for the aforementioned is almost similar to that of the first embodiment, similar reference characters are given to similar components and description thereof will not be repeated.

Write and erase operations of a memory cell in the embodiment will now be described.

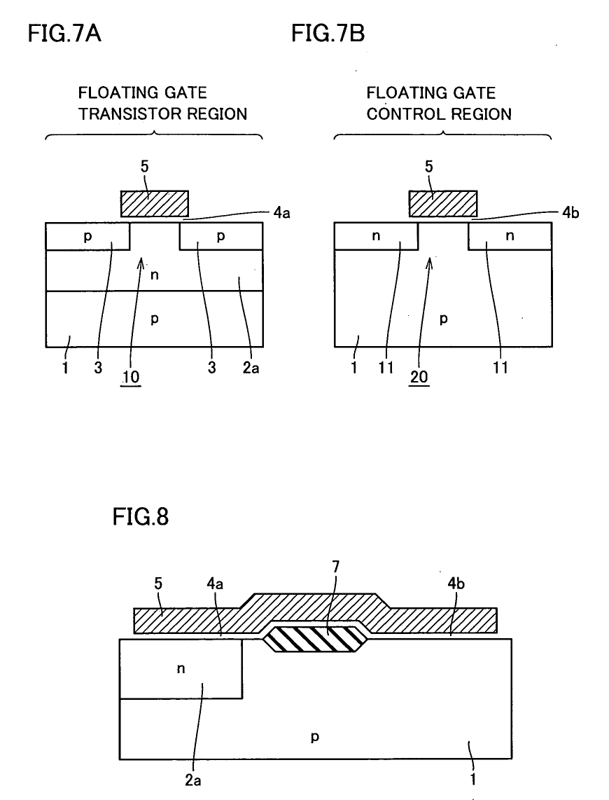

Referring to FIGS. 7A and 7B, a memory cell is written by injecting into floating gate 5 hot carriers resulting from impact ionization at floating gate transistor 10. The hot carriers are generated by applying to every region a voltage shown in table 3.

TABLE 3

| REGION WHERE VOLTAGE IS TO BE | |
|---|---|
| APPLIED | VOLTAGE |
| ONE P-TYPE IMPURITY DIFFUSED | 0 V |
| REGION 3 | |
| THE OTHER P-TYPE IMPURITY | ˜8 V |
| DIFFUSED REGION 3 | |
| ONE SOURCE/DRAIN IMPURITY | ˜10 V |
| DIFFUSED REGION 11 | |
| THE OTHER SOURCE/DRAIN | ˜10 V |
| IMPURITY DIFFUSED REGION 11 | |
| N-TYPE WELL REGION 2a | ˜8 V |
| P-TYPE SEMICONDUCTOR | 0 V |
| SUBSTRATE 1 | |

*Same voltage is applied to the other p-type impurity diffused region 3 and n-type well region 2a.

In this case, the pair of source/drain impurity diffused regions 11, 11 of control transistor 20 serves to control a potential of floating gate 5. More particularly, a maximum amount of hot carriers is generated when the floating gate 5 potential is approximately −1V (with reference to one p-type impurity diffused region 3). Accordingly, a voltage which can cause such potential is applied to the pair of source/drain impurity diffused regions 11, 11 to control the floating gate 5 potential.

A memory cell is erased by providing a high potential to one p-type impurity diffused region 3 (or the other p-type impurity diffused region 3) to cause Fowler-Nordheim (FN) tunneling, by which electrons accumulated at floating gate 5 are drawn. In order to cause FN tunneling, a positive potential as shown in table 4 is provided to one p-type impurity diffused region 3 (or the other p-type impurity diffused region 3).

TABLE 4

| REGION WHERE VOLTAGE IS TO BE | |
|---|---|
| APPLIED | VOLTAGE |
| ONE P-TYPE IMPURITY DIFFUSED | ˜−10 V |
| REGION 3 | |
| THE OTHER P-TYPE IMPURITY | ˜−10 V |
| DIFFUSED REGION 3 | |
| ONE SOURCE/DRAIN IMPURITY | ˜20 V |
| DIFFUSED REGION 11 | |
| THE OTHER SOURCE/DRAIN | 0 V |
| IMPURITY DIFFUSED REGION 11 | |
| N-TYPE WELL REGION 2a | 0 V |
| P-TYPE SEMICONDUCTOR | 0 V |
| SUBSTRATE 1 | |

*Same voltage is applied to one p-type impurity diffused region 3 and the other p-type impurity diffused region 3.
*Voltage to be applied to one source/drain impurity diffused region 11 and the other source/drain impurity diffused region 11 may be interchanged.

In this case, a negative voltages as shown in table 4 is also applied to the pair of p-type impurity diffused regions 3, 3 to lower the floating gate 5 potential (with reference to one p-type impurity diffused region 3). To perform an efficient erase operation, a junction capacitance ratio of floating gate 5 to one source/drain impurity diffused region 11 (or the other source/drain impurity diffused region 3) is preferably minimized to obtain a maximum potential difference.

According to the embodiment, since the pair of source/drain impurity diffused regions 11, 11 can control the floating gate 5 potential, a large potential difference can be provided between semiconductor substrate 1 and floating gate 5. Consequently, electrons in floating gate 5 can be drawn by exploiting the FN tunneling, which allows data to be electrically erased.

Additionally, floating gate transistor 10 is a p-channel MOS transistor. Therefore, similarly to the first embodiment, the embodiment can write data at a lower voltage than that using an n-channel MOS transistor.

Fourth Embodiment

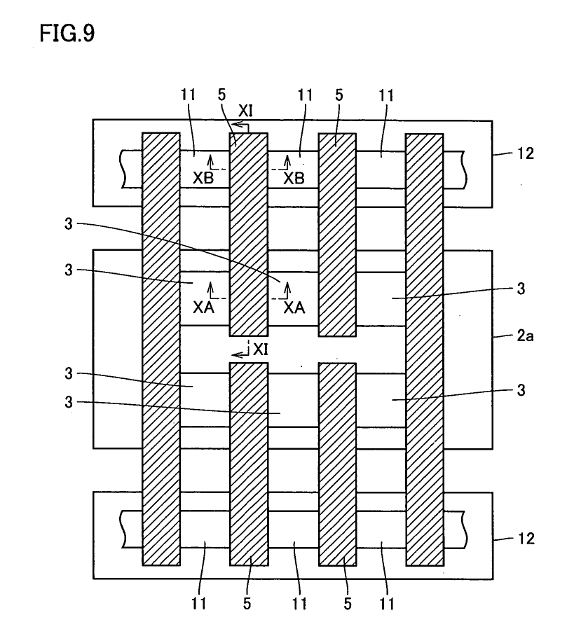

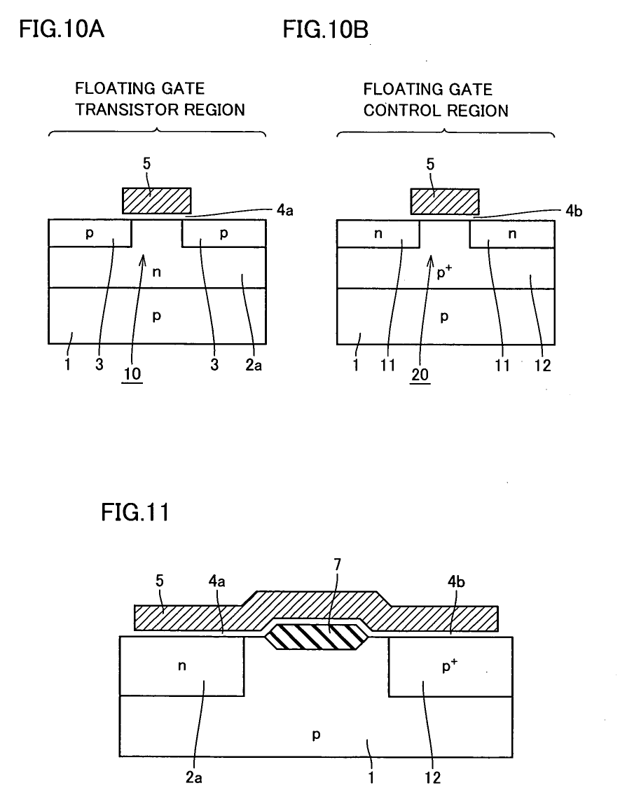

Referring to FIGS. 9 to 11, a configuration of a memory cell of the embodiment differs from that of the third embodiment in that it has an additional p-type well region 12 in the floating gate control region.

P-type well region 12 is formed at the main surface of semiconductor substrate 1. In p-type well region 12 is formed a pair of source/drain impurity diffused regions 11, 11. P-type well region 12 has higher carrier concentration than semiconductor substrate 1.

Since a configuration except for the aforementioned is almost similar to that of the third embodiment, similar reference characters are given to similar components and description thereof will not be repeated.

According to the embodiment, the following effect can be obtained.

In write and erase operations, when a voltage as shown in tables 3 and 4 is applied to n-type well region 2a and one source/drain impurity diffused region 11 (or the other source/drain impurity diffused region 11), a depletion layer is formed at pn junctions between n-type well region 2a and p-type semiconductor substrate 1 and between one source/drain impurity diffused region 11 (or the other source/drain impurity diffused region 11) and the p-type region. As the depletion layer extends further, leakage current associated with the punch-through increases.

According to the embodiment, since p-type well region 12 has higher carrier concentration than semiconductor substrate 1, further extension of the depletion layer can be suppressed. Consequently, the distance between n-type well region 2a and one source/drain impurity diffused region 11 (or the other source/drain impurity diffused region 11) can be reduced to provide a smaller-sized memory cell than the third embodiment.

Fifth Embodiment

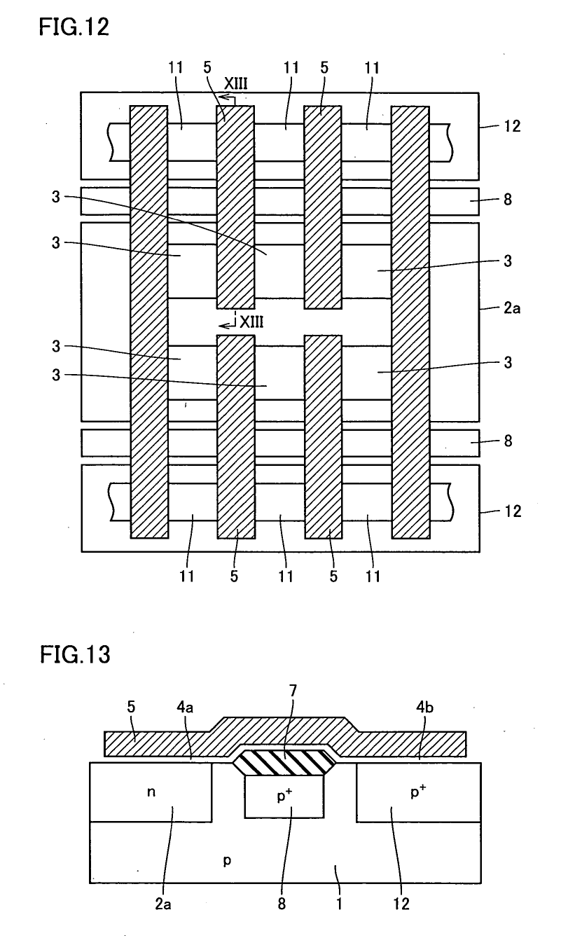

Referring to FIGS. 12 and 13, a configuration of a memory cell of the embodiment differs from that of the fourth embodiment in that it has p-type impurity diffused region 8 for device isolation.

P-type impurity diffused region 8 for device isolation is formed at semiconductor substrate 1 just below field insulating layer 7 which is formed at the main surface of semiconductor substrate 1 between the floating gate transistor region and the floating gate control region. P-type impurity diffused region 8 for device isolation has higher carrier concentration than semiconductor substrate 1.

Since a configuration except for the aforementioned is almost similar to that of the first embodiment, similar reference characters are given to similar components and description thereof will not be repeated.

According to the embodiment, the following effect can be obtained.

In write and erase operations, when a voltage as shown in tables 3 and 4 is applied to n-type well 2a and one source/drain impurity diffused region 11 (or the other source/drain impurity diffused region 11), a depletion layer is formed at pn junctions between n-type well region 2a and p-type semiconductor substrate 1 and between one source/drain impurity diffused region 11 (or the other source/drain impurity diffused region 11) and the p-type region. As the depletion layer extends further, leakage current associated with the punch-through increases.

According to the embodiment, since p-type impurity diffused region 8 for device isolation has higher carrier concentration than semiconductor substrate 1, further extension of the depletion layer can be suppressed. Consequently, the distance between n-type well region 2a and one source/drain impurity diffused region 11 (or the other source/drain impurity diffused region 11) can be reduced to provide a smaller-sized memory cell than the fourth embodiment.

Sixth Embodiment

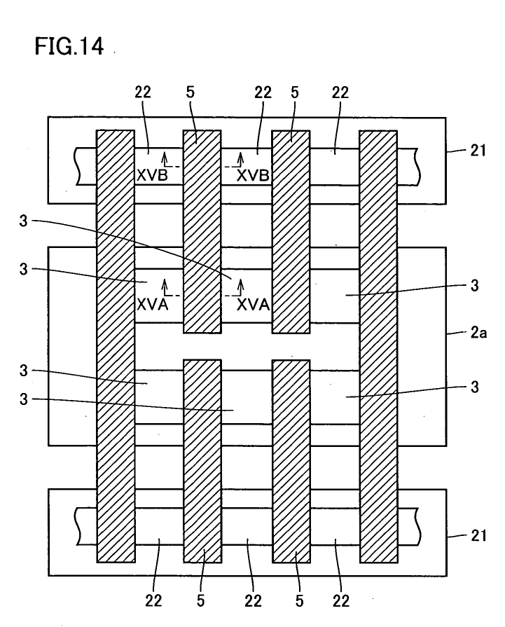

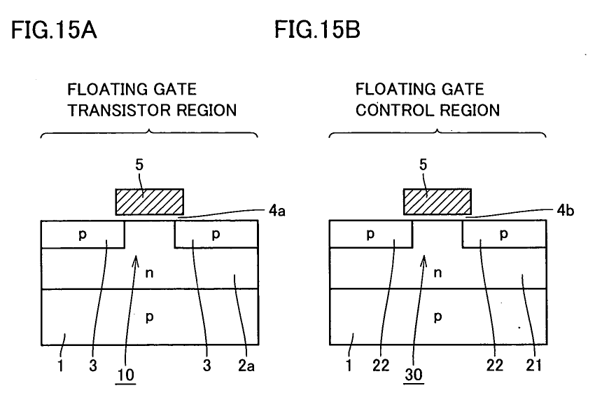

Referring to FIGS. 14 and 15, a configuration of a memory cell of the embodiment differs from that of the first embodiment in its configuration of an impurity diffused control region in the floating gate control region.

The impurity diffused control region of the embodiment is configured of a pair of p-type source/drain impurity diffused regions 22, 22. At the main surface of p-type semiconductor substrate 1 is formed an n-type well region 21. The pair of source/drain impurity diffused regions 22, 22 is formed at the main surface of p-type semiconductor substrate 1 in n-type well region 21 such that a region of semiconductor substrate 1 positioned below floating gate 5 is interposed between the paired source/drain regions. The pair of source/drain impurity diffused regions 22, 22, insulating layer 4b, and floating gate 5 configure a control transistor 30 which is a p-channel MOS transistor.

Since a configuration except for the aforementioned is almost similar to that of the first embodiment, similar reference characters are given to similar components and description thereof will not be repeated. Write and erase operations of a memory cell in the embodiment will now be described.

Referring to FIGS. 15A and 15B, a memory cell is written by injecting into floating gate 5 hot carriers resulting from impact ionization at floating gate transistor 10. The hot carriers are generated by applying to every region a voltage shown in table 5.

TABLE 5

| REGION WHERE VOLTAGE IS TO BE | |
|---|---|
| APPLIED | VOLTAGE |
| ONE P-TYPE IMPURITY DIFFUSED | 0 V |
| REGION 3 | |
| THE OTHER P-TYPE IMPURITY | ˜8 V |
| DIFFUSED REGION 3 | |
| ONE SOURCE/DRAIN IMPURITY | ˜5 V |
| DIFFUSED REGION 22 | |
| THE OTHER SOURCE/DRAIN | ˜5 V |
| IMPURITY DIFFUSED REGION 22 | |
| N-TYPE WELL REGION 2a | ˜8 V |
| N-TYPE WELL REGION 21 | ˜5 V |
| P-TYPE SEMICONDUCTOR | 0 V |
| SUBSTRATE 1 | |

*Same voltage is applied to the other p-type impurity diffused region 3 and n-type well region 2a.
*Same voltage is applied to one source/drain impurity diffused region 22, the other source/drain impurity diffused region 22, and n-type well region 21.

In this case, the pair of source/drain impurity diffused regions 22, 22 of control transistor 30 serves to control a potential of floating gate 5. More particularly, a maximum amount of hot carriers is generated when the floating gate 5 potential is approximately −1V (with reference to one p-type impurity diffused region 3). Accordingly, a voltage which can cause such potential is applied to the pair of source/drain impurity diffused regions 22, 22 and n-type well region 21 to control the floating gate 5 potential.

A memory cell is erased by providing a high potential to each of one source/drain impurity diffused region 22, the other source/drain impurity diffused region 22, and n-type well region 21 to cause FN tunneling, by which electrons accumulated at floating gate 5 are drawn. In order to cause FN tunneling, a positive potential as shown in table 6 is provided to one source/drain impurity diffused region 22 (or the other source/drain impurity diffused region 22) and n-type well region 21.

TABLE 6

| REGION WHERE VOLTAGE IS TO BE | |
|---|---|
| APPLIED | VOLTAGE |
| ONE P-TYPE IMPURITY DIFFUSED | ˜−10 V |
| REGION 3 | |
| THE OTHER P-TYPE IMPURITY | ˜−10 V |
| DIFFUSED REGION 3 | |
| ONE SOURCE/DRAIN IMPURITY | ˜15 V |
| DIFFUSED REGION 22 | |
| THE OTHER SOURCE/DRAIN | ˜15 V |
| IMPURITY DIFFUSED REGION 22 | |
| N-TYPE WELL REGION 2a | 0 V |
| N-TYPE WELL REGION 21 | ˜15 V |
| P-TYPE SEMICONDUCTOR | 0 V |
| SUBSTRATE 1 | |

*Same voltage is applied to one p-type impurity diffused region 3 and the other impurity diffused region 3.
*Same voltage is applied to one source/drain impurity diffused region 22, the other source/drain impurity diffused region 22, and n-type well region 21.

In this case, a negative voltage as shown in table 6 is also applied to the pair of p-type impurity diffused regions 3, 3 to lower the floating gate 5 potential (with reference to one p-type impurity diffused region 3). To perform an efficient erase operation, junction capacitance ratios between floating gate 5 and one source/drain impurity diffused region 22 and between the other source/drain impurity diffused region 22 and n-type well region 21 are preferably minimized to obtain a maximum potential difference.

According to the embodiment, since the pair of source/drain impurity diffused regions 22, 22 can control the floating gate 5 potential, a large potential difference can be provided between semiconductor substrate 1 and floating gate 5. Consequently, electrons in floating gate 5 can be drawn by exploiting the FN tunneling, which allows data to be electrically erased.

Additionally, floating gate transistor 10 is a p-channel MOS transistor. Therefore, similarly to the first embodiment, the embodiment can write data at a lower voltage than that using an n-channel MOS transistor.

Seventh Embodiment

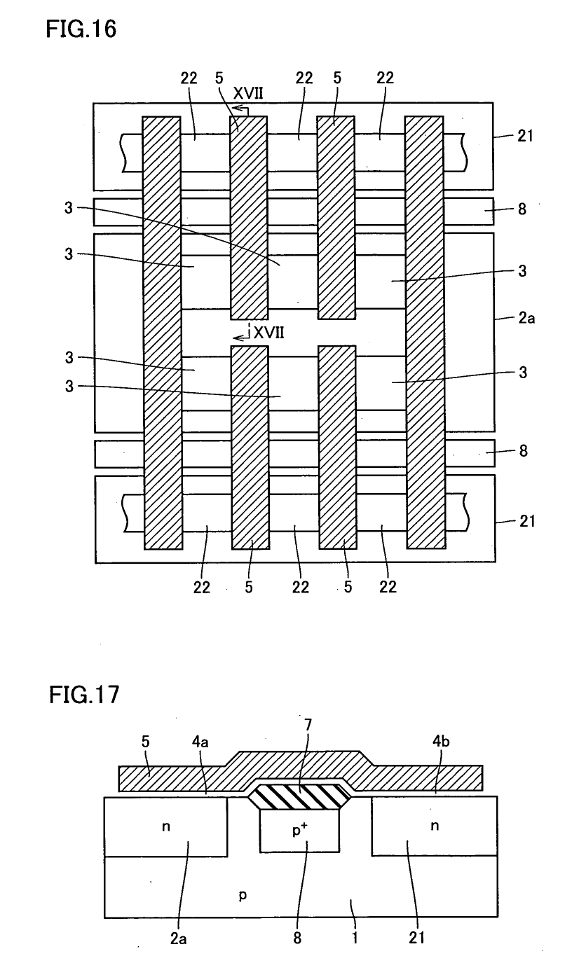

Referring to FIGS. 16 and 17, a configuration of a memory cell of the embodiment differs from that of the sixth embodiment in that it has a p-type impurity diffused region 8 for device isolation.

P-type impurity diffused region 8 for device isolation is formed at semiconductor substrate 1 just below field insulating layer 7 which is formed at the main surface of semiconductor substrate 1 between the floating gate transistor region and the floating gate control region. P-type impurity diffused region 8 for device isolation has higher carrier concentration than semiconductor substrate 1.

Since a configuration except for the aforementioned is almost similar to that of the first embodiment, similar reference characters are given to similar components and description thereof will not be repeated.

According to the embodiment, the following effect can be obtained.

In write and erase operations, when a voltage as shown in tables 5 and 6 is applied to n-type well region 21, a depletion layer is formed at a pn junction between p-type semiconductor substrate 1 and n-type well region 21. As the depletion layer extends further, leakage current associated with the punch-through increases.

According to the embodiment, since p-type impurity diffused region 8 for device isolation has higher carrier concentration than semiconductor substrate 1, further extension of the depletion layer can be suppressed. Consequently, the distance between n-type well region 2a and n-type well region 21 can be reduced to provide a smaller-sized memory cell than the sixth embodiment.

Eighth Embodiment

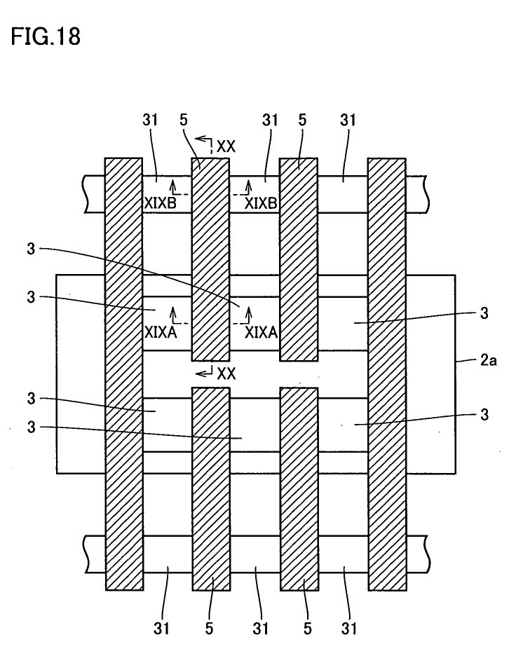

Referring to FIGS. 18 to 20, a configuration of a memory cell of the embodiment differs from that of the first embodiment in its configuration of an impurity diffused control region in the floating gate control region.

The impurity diffused control region of the embodiment is configured of an n-type impurity diffused region 31. N-type impurity diffused region 31 is formed at the main surface of p-type semiconductor substrate 1 and faces floating gate 5 with insulating layer 4b interposed therebetween.

Since a configuration except for the aforementioned is almost similar to that of the first embodiment, similar reference characters are given to similar components and description thereof will not be repeated.

Write and erase operations of a memory cell in the embodiment will now be described.

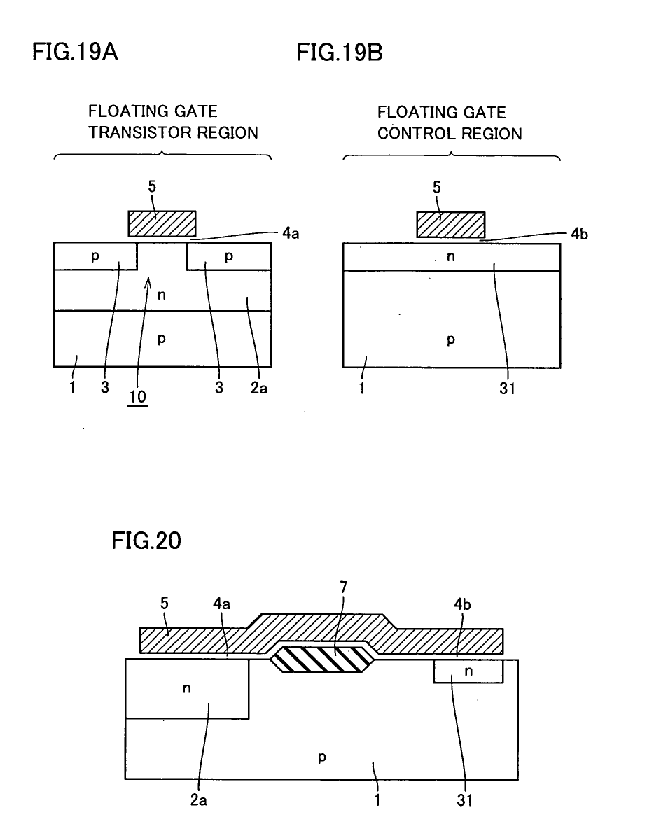

Referring to FIGS. 19A and 19B, a memory cell is written by injecting into floating gate 5 hot carriers resulting from impact ionization at floating gate transistor 10. The hot carriers are generated by applying to every region a voltage shown in table 7.

TABLE 7

| REGION WHERE | |
|---|---|
| VOLTAGE IS TO BE | |
| APPLIED | VOLTAGE |
| ONE P-TYPE IMPURITY | 0 V |
| DIFFUSED REGION 3 | |
| THE OTHER P-TYPE | ˜8 V |
| IMPURITY DIFFUSED | |
| REGION 3 | |
| IMPURITY DIFFUSED | ˜5 V |
| CONTROL REGION 31 | |
| N-TYPE WELL REGION 2a | ˜8 V |
| P-TYPE | 0 V |
| SEMICONDUCTOR | |
| SUBSTRATE 31 | |

*Same voltage is applied to the other p-type impurity diffused region 3 and n-type well region 2a.

In this case, impurity diffused control region (n-type impurity diffused region) 31 serves to control a potential of floating gate 5. More particularly, a maximum amount of hot carriers is generated when the floating gate 5 potential is approximately −1V (with reference to one p-type impurity diffused region 3). Accordingly, a voltage which can cause such potential is applied to impurity diffused control region 31 to control the floating gate 5 potential.

A memory cell is erased by providing a high potential to impurity diffused control region 31 to cause FN tunneling, by which electrons accumulated at floating gate 5 are drawn. In order to cause FN tunneling, a positive potential as shown in table 8 is provided to impurity diffused control region 31.

TABLE 8

| REGION WHERE | |
|---|---|
| VOLTAGE IS TO BE | |
| APPLIED | VOLTAGE |
| ONE P-TYPE IMPURITY | ˜−10 V |
| DIFFUSED REGION 3 | |
| THE OTHER P-TYPE | ˜−10 V |
| IMPURITY DIFFUSED | |
| REGION 3 | |
| IMPURITY DIFFUSED | ˜15 V |
| CONTROL REGION 31 | |
| N-TYPE WELL REGION 2a | 0 V |
| P-TYPE | 0 V |
| SEMICONDUCTOR | |
| SUBSTRATE 31 | |

*Same voltage is applied to one p-type impurity diffused region 3 and the other p-type impurity diffused region 3.

In this case, a negative voltage as shown in table 6 is also applied to the pair of p-type impurity diffused regions 3, 3 to lower the floating gate 5 potential (with reference to one p-type impurity diffused region 3). To perform an efficient erase operation, junction capacitance ratios of floating gate 5 to one p-type impurity diffused region 3, the other p-type impurity diffused region 3, and n-type well region 2a respectively are preferably minimized to obtain a maximum potential difference.

According to the embodiment, since impurity diffused control region 31 can control the floating gate 5 potential, a large potential difference can be provided between semiconductor substrate 1 and floating gate 5. Consequently, electrons in floating gate 5 can be drawn by exploiting the FN tunneling, which allows data to be electrically erased.

Additionally, floating gate transistor 10 is a p-channel MOS transistor. Therefore, similarly to the first embodiment, the embodiment can write data at a lower voltage than that using an n-channel MOS transistor.

Ninth Embodiment

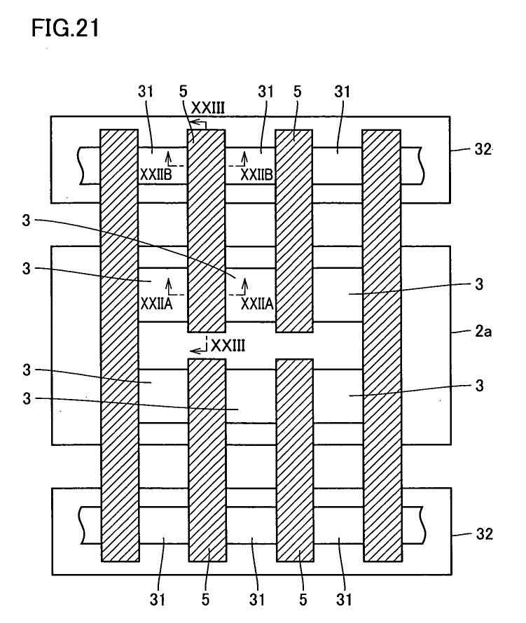

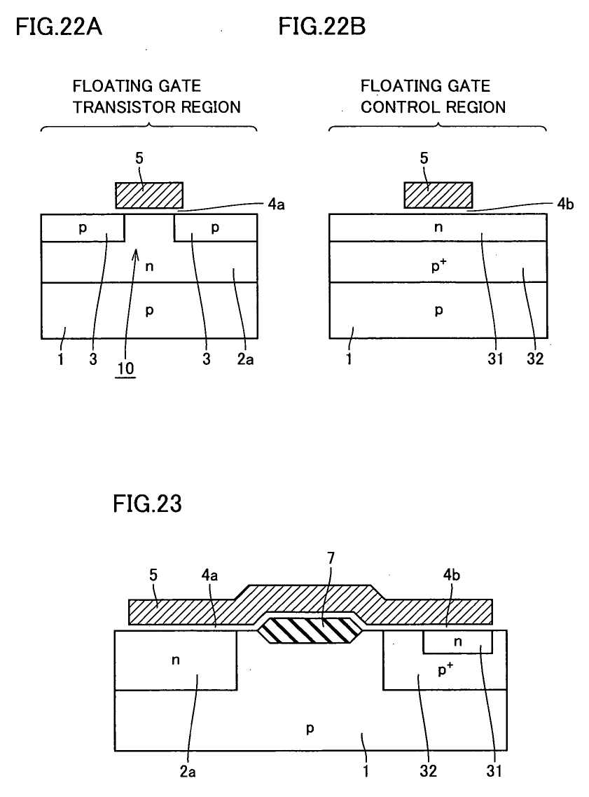

Referring to FIGS. 21 to 23, a configuration of a memory cell of the embodiment differs from that of the eighth embodiment in that it has an additional p-type well region 32 in the floating gate control region.

P-type well region 32 is formed at the main surface of semiconductor substrate 1. In p-type well region 32 is formed impurity diffused control region (n-type impurity diffused region) 31. P-type well region 12 has higher carrier concentration than semiconductor substrate 1.

Since a configuration except for the aforementioned is almost similar to that of the third embodiment, similar reference characters are given to similar components and description thereof will not be repeated.

According to the embodiment, the following effect can be obtained.

In write and erase operations, when a voltages as shown in tables 7 and 8 is applied to n-type well region 2a and impurity diffused control region (n-type impurity diffused region) 31, a depletion layer is formed at pn junctions between n-type well region 2a and p-type semiconductor substrate 1 and between impurity diffused control region (n-type impurity diffused region) 31 and the p-type region. As the depletion layer extends further, leakage current associated with the punch-through increases.

According to the embodiment, since p-type well region 32 has higher carrier concentration than semiconductor substrate 1, further extension of the depletion layer can be suppressed. Consequently, the distance between n-type well region 2a and impurity diffused control region (n-type impurity diffused region) 31 can be reduced to provide a smaller-sized memory cell than the eighth embodiment.

Tenth Embodiment

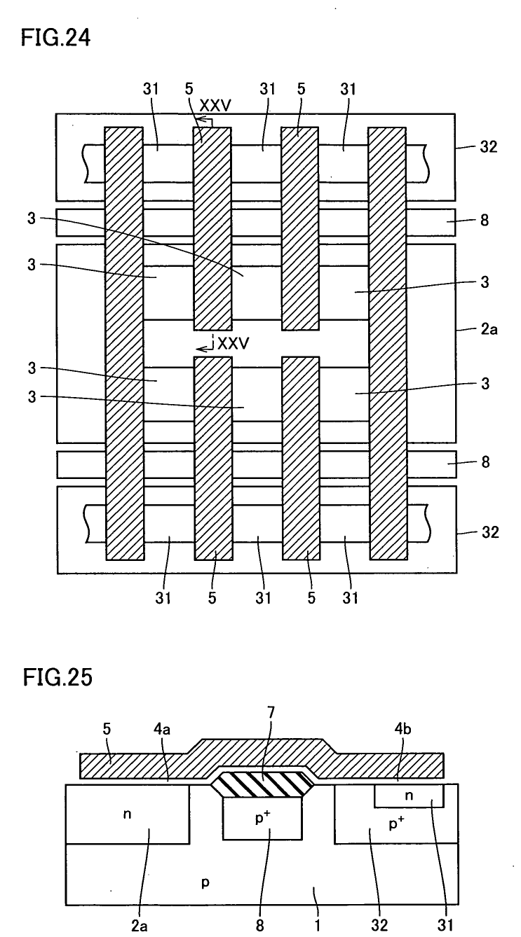

Referring to FIGS. 24 and 25, a configuration of a memory cell of the embodiment differs from that of the ninth embodiment in that it has p-type impurity diffused region 8 for device isolation.

P-type impurity diffused region 8 for device isolation is formed at semiconductor substrate 1 just below field insulating layer 7 which is formed at the main surface of semiconductor substrate 1 between the floating gate transistor region and the floating gate control region. P-type impurity diffused region 8 for device isolation has higher carrier concentration than semiconductor substrate 1.

Since a configuration except for the aforementioned is almost similar to that of the first embodiment, similar reference characters are given to similar components and description thereof will not be repeated.

According to the embodiment, the following effect can be obtained.

In write and erase operations, when a voltage as shown in tables 7 and 8 is applied to n-type well region 2a, a depletion layer is formed at a pn junction between p-type semiconductor substrate 1 and n-type well region 2a. As the depletion layer extends further, leakage current associated with the punch-through increases.

According to the embodiment, since p-type impurity diffused region 8 for device isolation has higher carrier concentration than semiconductor substrate 1, further extension of the depletion layer can be suppressed. Consequently, the distance between n-type well region 2a and n-type well region 31 can be reduced to provide a smaller-sized memory cell than the ninth embodiment.

Although the present invention has been described and illustrated in detail, it is clearly understood that the same is by way of illustration and example only and is not to be taken by way of limitation, the spirit and scope of the present invention being limited only by the terms of the appended claims.

1. A nonvolatile semiconductor memory device comprising:
a semiconductor substrate having a main surface;
a pair of p-type impurity diffused regions formed at the main surface of said semiconductor substrate to serve as source/drain;
a floating gate formed on a region of said semiconductor substrate lying between the paired p-type impurity diffused regions with a tunnel insulating layer interposed between said floating gate and said semiconductor substrate; and
an impurity diffused control region formed at the main surface of said semiconductor substrate to control a potential of said floating gate.

2. The nonvolatile semiconductor memory device according to claim 1, wherein said impurity diffused control region is of p-conductivity type and faces said floating gate with an insulating layer interposed therebetween.

3. The nonvolatile semiconductor memory device according to claim 1, wherein said impurity diffused control region is a pair of source/drain impurity diffused regions formed at the main surface of said semiconductor substrate such that a region of said semiconductor substrate positioned below said floating gate is interposed between the paired source/drain impurity diffused regions.

4. The nonvolatile semiconductor memory device according to claim 3, wherein said pair of source/drain impurity diffused regions is of n-conductivity type.

5. The nonvolatile semiconductor memory device according to claim 4 further comprising a p-type well region formed at the main surface of said semiconductor substrate, wherein said pair of n-conductivity type source/drain impurity diffused regions is formed in said p-type well region.

6. The nonvolatile semiconductor memory device according to claim 3, wherein said pair of source/drain impurity diffused regions is of p-conductivity type.

7. The nonvolatile semiconductor memory device according to claim 6 further comprising an n-type well region formed at the main surface of said semiconductor substrate, wherein said p-conductivity type source/drain impurity diffused region is formed in said n-type well region.

8. The nonvolatile semiconductor memory device according to claim 1, wherein said impurity diffused control region is of n-conductivity type and faces said floating gate with an insulating layer interposed therebetween.

9. The nonvolatile semiconductor memory device according to claim 8 further comprising a p-type well region formed at the main surface of said semiconductor substrate, wherein said impurity diffused control region of n-type is formed in said p-type well region.

10. The nonvolatile semiconductor memory device according to claim 1 further comprising:
a field insulating layer formed at the main surface of said semiconductor substrate between a region where said pair of p-type impurity diffused region is formed and a region where said impurity diffused control region is formed; and
a p-type impurity diffused region for device isolation formed at said semiconductor substrate just below said field insulating layer.
